(19) United States
(12) Patent Application Publication
(10) Pub. No.: US 2025/0203875 A1
(43) Pub. Date: Jun. 19, 2025

(54) METHOD FOR PREPARING AN ANTI-FERROELECTRIC MULTILAYER DEVICE

(71) Applicant: COMMISSARIAT A L'ENERGIE ATOMIQUE ET AUX ENERGIES ALTERNATIVES, Paris (FR)

(72) Inventors: Amanda Mallmann Tonelli, Grenoble (FR); Messaoud Bedjaoui, Grenoble (FR); Laurent Grenouillet, Grenoble (FR); Vincent Jousseaume, Grenoble (FR)

(73) Assignee: COMMISSARIAT A L'ENERGIE ATOMIQUE ET AUX ENERGIES ALTERNATIVES, Paris (FR)

(21) Appl. No.: 18/980,029

(22) Filed: Dec. 13, 2024

(30) Foreign Application Priority Data
Dec. 15, 2023 (FR) 2314316

(51) Int. Cl. H10B 53/30

(52) U.S. Cl. CPC H10B 53/30

(57) ABSTRACT

The present disclosure relates to a method for preparing an anti-ferroelectric multilayer device, in particular an ultrafine device, comprising an alternation of at least one layer of a first type and at least one layer of a second type.

### CROSS-REFERENCE TO RELATED APPLICATION

This application claims priority to French Application No. 2314316, filed on Dec. 15, 2023, the entire contents of which is enclosed herein in its entirety.

### BACKGROUND

The advent of microelectronic, nanoelectronic and optronic applications using the internet of things has set in motion a fast-paced race to manufacture increasingly complex integrated circuits.

The basic criteria for these new devices are their very high integrability, compatibility with the complementary metal-oxide-semiconductor (CMOS) technology combined with a very low energy consumption.

To meet these requirements, the use of advanced materials that are scalable in terms of thickness and performance in the construction and manufacture of these devices has become essential. Among the materials used in this type of microelectronic devices, there is the family of anti-ferroelectric (AF) materials. The anti-ferroelectric AF materials and layers are pyroelectric materials with a non-centrosymmetric crystallographic class. From a macroscopic point of view, the AF materials form a subset of anti-polar crystals unlike ferroelectric materials which form a single subset of polar crystals. The experimental expression of anti-ferroelectric behaviour is a double hysteresis cycle of polarisation as a function of electric field. From a structural point of view, the elementary lattice of AF materials is generally characterised by the dominance of a tetragonal crystallographic phase.

From an application point of view, and unlike ferroelectric materials, where the interest has increased sharply since the discovery of ferroelectricity in ultra-thin films of hafnium oxide HfO₂ in 2011, the use of anti-ferroelectric materials in thin films (<100 nm) remains limited. In practice, it is possible to use MIM (Metal-Insulator-Metal) stacks incorporating an anti-ferroelectric layer acting as high permittivity insulating dielectric as energy storage device. This case corresponds to “MAFM” type structures for Metal-Anti Ferroelectric-Metal. In certain configurations, anti-ferroelectric AF layers can be used to manufacture very high-density capacitors coupled with transistors for embedded memory applications such as DRAM (Dynamic Random Access Memory).

Over the last few years, a number of developments have introduced anti-ferroelectrics AF in the production of a number of these devices. However, the proposed devices use AF layers with thicknesses generally greater than the critical values (8 to 10 nm), at the risk of degrading the anti-ferroelectric properties. This limitation in thickness reduces the field of application of anti-ferroelectric layers in devices such as the gates for the advanced node transistors or the manufacture of very high-density energy storage capacitors in substrates with very high topography.

However, in the case of a dielectric layer with a uniform and homogeneous physico-chemical and structural composition, reducing the thickness of said anti-ferroelectric layer is accompanied by an increase in the overall thermal budget above 500° C. in order to guarantee the formation of the crystallographic phase required to impart anti-ferroelectric properties to the manufactured capacitance. And this increase in the overall thermal budget above 500° C. is not compatible with the thermal budget requirement for BEOL (Back End Of Line) methods, whose maximum permitted temperatures are below 450° C.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

This disclosure relates to examples of a method for preparing an anti-ferroelectric multilayer device, in particular an ultrafine device, comprising an alternation of at least one layer of a first type and at least one layer of a second type.

One purpose of the disclosure is to enable the implementation of a method of preparing an anti-ferroelectric device which avoids the aforementioned disadvantages.

Thus, one aim of the disclosure is to provide a method for preparing an anti-ferroelectric device, in particular an ultrafine one, while allowing preservation of a thermal budget compatible with BEOL technology.

A more specific aim of the disclosure is to provide a method for preparing an anti-ferroelectric device allowing a reduction in the thickness of the anti-ferroelectric layers “AF” in a capacitance stack of the “MAFM” type, while allowing preservation of a thermal budget compatible with BEOL technology.

Thus, according to a first aspect, the disclosure concerns one or more examples of a method for preparing a multilayer anti-ferroelectric device M with n layers, n being greater than or equal to 2, consisting of or comprising an alternation of at least one layer A and at least one layer B,
the at least one layer A independently consisting of or comprising a compound selected from zirconium oxides (ZrO₂), hafnium and zirconium oxides (H₂O) enriched with zirconium and perovskites,
the at least one layer B being, independently, constituted by or comprising a compound selected from hafnium oxides (HfO₂), hafnium and zirconium oxides (H₂O) enriched with hafnium, hafnium and zirconium oxides (H₂O) doped with aluminium, hafnium and zirconium oxides (H₂O) doped with lanthanum, hafnium and zirconium oxides (H₂O) doped with gadolinium, hafnium and zirconium oxides (H₂O) doped with yttrium, hafnium and zirconium oxides (H₂O) doped with silicon, and hafnium oxides (HSO) doped with silicon,
the method comprising the following steps:
a step of preparing, on a substrate or a lower metal electrode, a multilayer device M′ with n′ layers, n′ being greater than or equal to 3, comprising an alternation of the layers A and B, the first of the n′ layers, in contact with the lower metal electrode, being a layer A,
a step of depositing on the multilayer device M′ obtained at the end of step (i), opposite the lower metal electrode, an upper metal electrode,
a step of annealing the device obtained at the end of step (ii),
a step of removing the upper metal electrode from the device obtained at the end of step (iii),
a selective etching of the n′-n upper layers, opposite to the lower metal electrode, for example completely, in order to obtain the multilayer device M on the lower metal electrode,
optionally, a step of depositing, on the multilayer device M′ obtained at the end of step (v), opposite the lower metal electrode, an upper metal electrode.

According to another aspect, the disclosure relates to examples of a method for preparing a multilayer anti-ferroelectric device M with n layers, n being between 2 and 100, preferably between 2 and 25, consisting of or comprising an alternation of at least one layer A and at least one layer B,
the at least one layer A being independently constituted of or comprising a compound selected from zirconium oxides (ZrO₂), hafnium and zirconium oxides (H₂O) enriched with zirconium and perovskites, the at least one layer B being, independently, constituted of or comprising a compound selected from hafnium oxides (HfO₂), hafnium and zirconium oxides (H₂O) enriched with hafnium, hafnium and zirconium oxides (H₂O) doped with aluminium, hafnium and zirconium oxides (H₂O) doped with lanthanum, hafnium and zirconium oxides (H₂O) doped with gadolinium, hafnium and zirconium oxides (H₂O) doped with yttrium, hafnium and zirconium oxides (H₂O) doped with silicon, and hafnium oxides (HSO) doped with silicon,
the method comprising the following steps:
a step of preparing, on a substrate or a lower metal electrode, a multilayer anti-ferroelectric device M with n′ layers, n′ being from 3 to 101, with n′>n, preferably between 3 and 26, comprising an alternation of the layers A and B, the first of the n′layers, in contact with the lower metal electrode, being a layer A,
a step of depositing on the multilayer device M′ obtained at the end of step (i), opposite the lower metal electrode, an upper metal electrode,
a step of annealing the device obtained at the end of step (ii),
a step of removing the upper metal electrode from the device obtained at the end of step (iii),
a selective etching of the n′-n upper layers, opposite to the lower metal electrode, in particular completely, in order to obtain the multilayer device M on the lower metal electrode,
optionally, a step of depositing on the multilayer device M′ obtained at the end of step (v), opposite the lower metal electrode, an upper metal electrode.

According to a particular embodiment, the method comprises the following steps:
a step of preparing on a substrate or a lower metal electrode a multilayer device M′ with n′ layers, n′ being from 3 to 101, with n′>n, preferably between 3 and 26, comprising an alternation of the layers A and B, the first of the n′ layers, in contact with the lower metal electrode, being a layer A,
a step of depositing on the multilayer device M′ obtained at the end of step (i), opposite the lower metal electrode, an upper metal electrode,
a step of annealing the device obtained at the end of step (ii),
a step of removing the upper metal electrode from the device obtained after step (iii),
a selective etching of the n′-n upper layers, opposite to the lower metal electrode, in particular completely, in order to obtain the multilayer device M on the lower metal electrode,
a step of depositing on the multilayer device M′ obtained at the end of step (v), opposite of the the lower metal electrode, an upper metal electrode.

### DESCRIPTION OF THE DRAWINGS

The foregoing aspects and many of the attendant advantages of the disclosed subject matter will become more readily appreciated as the same become better understood by reference to the following detailed description, when taken in conjunction with the accompanying drawings, wherein:

FIG. 1 illustrates a device obtained using a process according to the disclosure as described in example 1, step 1.

FIG. 2 illustrates a device obtained using a method according to the disclosure as described in example 1, step 2.

FIG. 3 illustrates the X-ray grazing incident diffraction spectrum, GIXRD for Grazing Incident X-ray Diffraction, of a device as described in Example 1, Step 2.

FIG. 4 illustrates a device obtained using a method according to the disclosure as described in example 1, step 2.

FIG. 5 illustrates a device obtained using a method according to the disclosure as described in example 1, step 2.

FIG. 6 illustrates a device obtained using a method according to the disclosure as described in example 1, step 3.

FIG. 7 illustrates device obtained using a method according to the disclosure as described in example 1, step 3.

FIG. 8 illustrate a device obtained using a method according to the disclosure as described in example 1, step 4.

FIG. 9 illustrates device obtained using a method according to the disclosure as described in example 1, step 4.

### DETAILED DESCRIPTION

“Hafnium and zirconium oxides (H₂O) enriched with zirconium” refers in particular to hafnium and zirconium oxides comprising more than 50% at (atomic concentration) of ZrO₂.

Examples of perovskites include lead zirconate (PbHfO₃), and lead hafniate (PbHfO₃).

Examples of perovskites include lead zirconate (PbHfO₃), lead hafniate (PbHfO₃), PZT/PZO-type perovskites for Pb(Zr, Ti)O₃, barium and strontium titanates (BST), and lead-free perovskites (e.g. LNO for LiNbO₃, BFO for BiFeO₃, NBT for Na_{0.5}Bi_{0.5}TiO₃)

“Hafnium and zirconium oxides (H₂O) enriched with hafnium” refers in particular to hafnium and zirconium oxides comprising more than 50% at HfO₂.

The term “hafnium and zirconium oxides (H₂O) doped with aluminium” refers in particular to hafnium and zirconium oxides comprising from 0.1 to 10% at, preferably about 1% at, of Al₂O₃.

The term “hafnium and zirconium oxides (H₂O) doped with lanthanum” refers in particular to the hafnium and zirconium oxides comprising 0.1 to 10% at, preferably about 1% at, of lanthanum.

The term “hafnium and zirconium oxides (H₂O) doped with gadolinium” refers in particular to the hafnium and zirconium oxides comprising 0.1 to 10% at, preferably about 1% at, of gadolinium.

The term “hafnium and zirconium oxides (H₂O) doped with yttrium” refers in particular to the hafnium and zirconium oxides comprising 0.1 to 10% at, preferably about 1% at, of yttrium.

The term “hafnium and zirconium oxides (H₂O) doped with silicon” refers in particular to the hafnium and zirconium oxides comprising from 0.1 to 10% at, preferably about 1% at, of SiO₂.

The term “hafnium oxides (HSO) doped with silicon” refers in particular to the hafnium oxides comprising from 0.1 to 10% at, preferably about 1% at, of SiO₂.

By “anti-ferroelectric multilayer device M” we mean in particular that the multilayer device is, when considered as a whole, anti-ferroelectric. The device is therefore generally anti-ferroelectric, even if this is not necessarily the case for all the layers of the device.

Surprisingly, it has also been shown that the multilayer device M is anti-ferroelectric, despite the presence of layers that may not be anti-ferroelectric, or even be ferroelectric.

And just as surprisingly, the nature and position of layers A and B as defined above allows us to obtain a definite and well-defined anti-ferroelectric multilayer device.

Without wishing to restrict ourselves to any particular theory, annealing helps to promote formation of a crystallographic phase with tetragonal dominance for unit layer A and monoclinic dominance for unit layer B.

And beneficially, to obtain said final device M without going through the step of etching of the upper layers (i.e. with annealing of the desired number of initial layers), it would be necessary to carry out the annealing step at approximately 800° C., which is incompatible with the components already present on the substrate. By producing a greater number of layers (M′ stack), annealing can be carried out at a much lower temperature, for example around 400° C., which is perfectly compatible with the components already present on the substrate.

The structure, properties and very nature of the layers of the multilayer device obtained by the method of the disclosure are totally different from those of a stack of (A/B) n layers with n≥1, in particular due to their crystallographic nature. And the same applies to the device after etching, in relation to a set of initial layers (A/B), arbitrarily reduced by the layers corresponding to those etched.

For the above reasons, the function (and therefore the interest) of selective etching as defined within the framework of the present disclosure is completely different from that of simple monolayer etching A/B.

Anti-ferroelectric” refers in particular to a device which has anti-parallel dipole moments. The hysteresis cycle for this type of material is typically, and by definition, extremely short.

The Direct measurement of a material's anti-ferroelectricity generally involves electrically exciting the material to be characterized, nested between two electrodes, to reveal the presence and characteristics of a hysteresis cycle.

By “a layer A (or B) being, independently, constituted by or comprising . . . ”, we mean in particular that the layers A can be different from one another, while always being constituted by or comprising a compound selected from the group defined above.

According to a particular embodiment, the layers A (when there is more than one) and/or the layers B (when there is more than one) consist of or comprise the same compound as defined above.

Thus, the device M, after step (iii) and after step (vi), when step (vi) is carried out, corresponds to a MAFM device (for “Metal Anti-Ferroelectric Metal”), the preparation of which consists of depositing an anti-ferroelectric multilayer material, in particular by ALD, between two metal electrodes.

In a particular embodiment, n ranges from 2 to 25, in particular from 2 to 20, n being 3 for example.

According to a particular embodiment, n′ ranges from 3 to 26, in particular from 3 to 21, n′ being 5, for example.

According to a particular embodiment, the last layer of the multilayer device M is a layer A.

The “last layer of the multilayer device M” refers in particular to the layer furthest from the substrate or the lower metal electrode.

According to a particular embodiment, the substrate is a substrate made of or comprising silicon.

According to a particular embodiment, the multilayer device M′ is prepared by successive deposition of layers A and B, in particular by an atomic layer deposition (ALD) technique.

The atomic layer deposition technique is likely to be able to develop conformal, homogeneous thin layers while controlling thickness with sub-nanometre precision.

Typically, the ALD process begins by flooding the reaction chamber with a precursor that coats (or ‘adsorbs’) the exposed surface of the substrate. This process is referred to as self-limiting, as the precursor can only adsorb on exposed areas; once all these are covered, the adsorption stops. A second gas is then introduced and reacts with the precursor to form the desired material. This second step is also self-limiting: once the available precursor sites have been exhausted, the reaction stops. These two steps are repeated until the desired film thickness is achieved. The growth rate is generally quantified by growth per cycle (GPC). The typical ALD cycle consists of two half-cycles of sequential doses of precursor and co-reactant, separated by purging and pumping steps, leading to self-limiting layer growth. The co-reactants and oxidants are generally sources of oxygen (H₂O or oxygen plasma). To obtain the multilayer material, different ALD monolayers are produced, alternating the pulses of precursors.

According to a particular embodiment, the precursors of hafnium and zirconium oxides, when deposited by an atomic layer deposition technique, are halogenated precursors, in particular HfCl₄ and ZrCl₄ respectively.

According to another particular embodiment, organometallic precursors such as TDMAZ (for Tetrakis-dimethylamino-zirconium-IV) can be used.

According to another embodiment, the multilayer device M′ is prepared by successive deposition of layers A and B, in particular by a PVD (Physical Vapour Deposition) or PLD (Pulsed Laser Deposition) deposition technique.

According to a particular embodiment, layers A and/or B of multilayer device M and/or multilayer device M′ have a thickness of between 0.5 and 5 nm, in particular around 2 nm.

According to a particular embodiment, the layers A have a thickness of between 0.5 and 5 nm, preferably around 2 nm, and the B layers have a thickness of between 0.5 and 5 nm, preferably around 2 nm.

According to a particular embodiment, the multilayer device M and/or the multilayer device M′ have a thickness of less than 50 nm, in particular less than or equal to 15 nm, in particular less than or equal to 10 or 6 nm.

The removal of step (iv) can be achieved using state-of-the-art techniques such as inductively coupled plasma reactive ion etching (ICP-RIE), for example by using halogen-based chemistry (Cl₂, BCl₃, CHF₃) in association with other gases (Ar, N₂, O₂, He).

Other chemical removal techniques can be used, for example to remove the titanium nitride layer, such as the mixture formed by the chemical elements ammonia hydroxide (NH₄OH), hydrogen peroxide H₂O₂ and deionised water H₂O heated to 60° C.

The etching in step (v) reduces the thickness of the total stack.

Without wishing to restrict ourselves to any theory, the etching of layers A and B in step (v) is selective because it exploits the difference in orientation/structure of said layers A and B. In contrast, this selectivity is not achieved by a standard, uniform and homogeneous ferroelectric material, in which the components of layers A and B would be mixed.

Experimentally, and as is well known to those skilled in the art, the thicknesses of the structures can be controlled according to the immersion or etching time and the chemical composition of the liquids used.

According to a particular embodiment, the selective etching in step (v) is a total etching of the upper n′-n layers, opposite the lower metal electrode (200).

According to another particular embodiment, the selective etching in step (v) is partial (so it's not total). In this case, some or all of the upper n′-n layers are only partially etched and remain on the device M.

According to a particular embodiment, the selective etching in step (v) is a wet or dry etching, in particular an etching (ALE), for example plasma etching (anisotropic), or thermal etching (isotropic).

In general, and as is well known to those skilled in the art, there are two main classes of etching method: the wet etching, where the material is dissolved when immersed in a chemical solution. And dry etching, where the material is sprayed or dissolved using reactive ions or a vapour-phase etchant. When said material is dissolved, and without wishing to restrict ourselves to any particular theory, it is typically the reaction of the material with ions or other substances that creates volatile species.

The speed at which the etching process occurs is called the etching speed. The etching process is said to be isotropic if it proceeds in all directions at the same speed. If it takes place in a single direction and is strongly dependent on the crystalline structure of the material, then it is anisotropic. An important consideration in any etching process is the ‘selectivity’ of the etchant. The selectivity is achieved when two different materials have different etching speeds under the same conditions or when one material is severe while the other is not. The selectivity is measured as the ratio between the different etching speeds of the etchant for different materials. The anisotropic etching is made possible by the distinct crystalline structures and orientations of the different materials making up the multilayer structure. The exposure to different etching speeds or chemical compositions is based on the crystallinity of the material.

For example, in the case of an HfO₂ and ZrO₂ multilayer structure, a thermal atomic layer etching (ALE) can be carried out using fluorination and ligand exchange reactions. HF can be used, for example, for fluorination and Sn(acac)₂, AlCI(CH₃)₂[dimethylaluminium chloride (DMAC)] or TiCl₄ used as metal precursors for ligand exchange. The so-called Atomic layer etching (ALE) method is used to remove thin films with Angstrom-like precision using sequential and self-limiting surface reactions.

According to a particular embodiment, the disclosure relates to a method as described above, in which:

The layer A of the device M′ is predominantly tetragonal;

The layer A of the device M is predominantly tetragonal.

The layer B of the device M′ is predominantly amorphous;

The layer B of the device M is predominantly orthorhombic and/or monoclinic.

In particular, “predominantly amorphous, orthorhombic or tetragonal” means that the layer is more than 50% amorphous, orthorhombic or tetragonal, respectively.

According to a particular embodiment, a part of the annealing step (iii) may be confused with step (ii). By way of example, the thermal budget of the method ALD (400° C. for 15 mn) typically required to deposit an upper electrode layer of 10 nm TiN may be sufficient for the crystallisation of the last layer A or B, in particular A.

The annealing can be carried out using any technique well known to the skilled person, such as rapid thermal annealing (RTA), or annealing using an oven, hot plate, radiation-assisted annealing, or laser annealing.

According to a particular embodiment, the annealing of step (iii) is carried out at a temperature of 300 to 600° C., in particular 300 to 500° C., in particular around 400° C.

According to a particular embodiment, step (vi) is carried out.

According to a particular embodiment, step (vi) is not followed by an annealing step.

According to a particular embodiment, the metal electrode mentioned in relation to step (ii) and/or the metal electrode mentioned in relation to step (vi) are deposited by physical vapour deposition (PVD) or chemical vapour deposition (CVD).

According to a particular embodiment, the lower metal electrode mentioned in relation to step (i) is in contact, opposite layer A, with a substrate.

According to a particular embodiment, the substrate is a substrate consisting of or comprising silicon.

According to a particular embodiment, the metal electrode mentioned in relation to step (i) is deposited by physical vapour deposition (PVD) or chemical vapour deposition (CVD).

According to a particular embodiment, the metal electrode mentioned in relation to step (i), the metal electrode mentioned in relation to step (ii) and/or the metal electrode mentioned in relation to step (vi) consist of or comprise a metal, in particular selected from titanium, gold, platinum aluminium, ruthenium, molybdenum, copper and tungsten, a material comprising said metal, in particular a metal nitride, for example TiN, WN, TaN or MoN, or mixtures thereof.

According to a particular embodiment, the metal electrode mentioned in relation to step (i), the metal electrode mentioned in relation to step (ii) and/or the metal electrode mentioned in relation to step (vi) have a thickness of between 2 or 5 and 500 nm, in particular from 2, 5 or 10 to 100 nm, in particular from 2 or 5 to 20 nm.

The substrate, or when absent, the lower metal electrode, can be planar or non-planar. Since all the layers described above (said at least one layer A, said at least one layer B, and when present, the lower metal electrode and/or the upper metal electrode) generally have a constant thickness (typically a thickness being ±10%, in particular ±1%, of its mean value), the assembly of layers described above has the same structural geometry as the substrate on which this assembly rests, or when this is absent, as the lower metal electrode on which it rests.

According to another aspect, the present disclosure also relates to a method for preparing three-dimensional structures comprising at least one device M as described above, in particular a plurality of devices M, which is prepared according to the steps as described above.

The device M according to the disclosure can be used in the preparation of anti-ferroelectric capacitors, in particular in a microelectronics or nanoelectronics device, for example in the field of energy storage, memories or transistors.

### Definitions

As understood here, value ranges in the form of “x-y” or “from x to y” or “between x and y” include the bounds x and y, the integers between these bounds, and all other real numbers between these bounds. For example, “1-5”, or “from 1 to 5” or “between 1 and 5” refers to the integers 1, 2, 3, 4 and 5, and all other real numbers between 1 and 5. Preferred embodiments include each individual integer in the value range, as well as any sub-combination of these integers and any set of real numbers between these integers. For example, the preferred values for “1-5” may comprise the integers 1, 2, 3, 4, 5, 1-2, 1-3, 1-4, 1-5, 2-3, 2-4, 2-5, etc.

As used in this description, the term “about” refers to a range of values within +10% of a specific value. For example, the term “about 20” comprises the values of 20±10%, i.e., the values of 18 to 22.

By layer we mean in particular a stratum of superimposed elements. This stratum generally refers to a layer whose physico-chemical and structural properties are uniform and homogeneous, both on the surface and in depth.

By first layer, we mean in particular a layer in contact with a second layer and, optionally, with a substrate.

By second layer, we mean in particular a layer in contact with the first layer and, where present, the third layer.

By third layer we mean, in particular, a layer in contact with the second layer and, where present, the fourth layer, and so on.

### Example 1: Preparation of a Device According to the Method of the Disclosure

### Step 1: Producing the Lower Electrode Layer

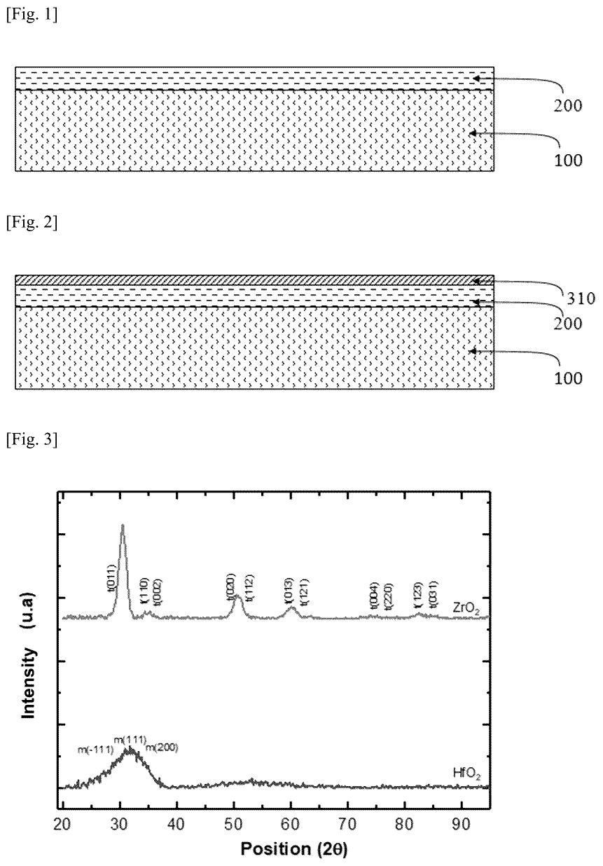

This step, illustrated in FIG. 1, involves producing a conductive layer (200) acting as a lower electrode on a standard substrate (100) generally made of silicon. The layer (200) is selected for its electrical conduction properties from the family of metals (titanium, gold, platinum, aluminium, tungsten, ruthenium, molybdenum, copper, etc.) or metal nitrides (TIN, WN, TaN, MON, etc.) or a mixture of several elements. In the example of FIG. 1, the TiN titanium nitride layer (200) with a thickness of 2 to 20 nm, in particular of 10 nm, is manufactured by state-of-the-art techniques. In particular, it is manufactured using the ALD (for Atomic Layer Deposition) method at 400° C. by sequentially injecting/purging TiCl₄ and NH₃ chemical precursors. Optionally, the 10 nm TiN layer can be produced at a temperature of 200° C. using the plasma-assisted ALD mode and the precursors TDMAT (for tetrakis-dimethylamino-titanium) and NH₃. Other thin-film deposition techniques (CVD for Chemical Vapour Deposition, PVD for Physical Vapour Deposition) can be used to manufacture the lower electrode layer.

### Step 2: Producing the Anti-Ferroelectric Layer

Firstly, step 2, illustrated in FIG. 2, consists in depositing the lower electrode (200) a unit layer (310) with a thickness of between 0.5 nm and 10 nm. In this example, the thickness of the layer (310) is fixed at 2 nm. Said layer is generally characterised by a crystalline structure. It is formed from one metal oxide or a combination of several metal oxides. Preferably, this is a layer of zirconium oxide ZrO₂ deposited by thermal ALD at 300° C. using the precursor ZrCl₄ used as a metallic reactant, and water H2O as an oxidant. Optionally, organometallic precursors (such as TDMAZ for Tetrakis-dimethylamino-zirconium-IV) or alternative techniques to ALD such as PVD (Physical Vapour Deposition) or PLD (Pulsed Laser Deposition) can be used to deposit the ZrO₂ layer, giving a dominant crystalline phase after the deposition step. A tetragonal crystalline structure of the ZrO₂ (310) unit layer can be defined by the presence of characteristic peaks according to the GIXRD graph in FIG. 3 (Grazing Incident X-ray Diffraction, GIXRD: this technique is often used to characterise the crystalline structure of thin and ultra-thin layers by measuring the intensity of an X-ray beam in relation to the diffraction angle).

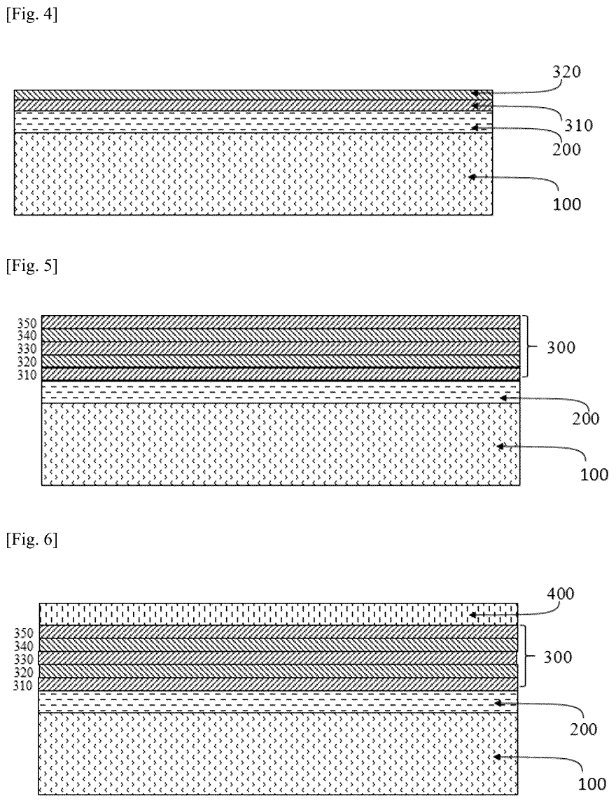

Secondly, the construction of the anti-ferroelectric layer requires the deposition of a second unit layer (320) in direct contact with the unit layer (310) as shown in FIG. 4. With a thickness of between 0.5 nm and 10 nm (and preferably 2 nm), this second layer (320) has an amorphous or predominantly amorphous mesh structure after the deposition step. It is formed from a metal oxide or a combination of several metal oxides. In the preferred example, this is a layer of hafnium oxide HfO₂ deposited by thermal ALD at 300° C. using the precursor HfCl₄, employed as a metallic reactant, and water H₂O as an oxidant. Optionally, organometallic precursors (such as TDMAH for Tetrakis-dimethylamino-hafnium-IV) or alternative techniques to ALD such as PVD (Physical Vapour Deposition) or PLD (Pulsed Laser Deposition) can be used for the deposition of the HfO₂ layer to obtain a dominant amorphous phase after the deposition step. Experimentally, a unit layer is said to be amorphous when the crystallisation peaks of the elementary lattice structure are either completely absent or only minimally present. This is particularly the case for the HfO₂ layer, the characteristic peaks of which after the deposition step are shown in the spectrum in FIG. 3.

The purpose of step 2 of this example is to build a multilayer structure (300) by using an elementary brick of two different materials noted “A” and “B” in this document and corresponding, respectively, to the unit layers (310) and (320). According to the preferred method, the unit layers (310) and (320) are alternated and iterated (3 times for layer 310 and 2 times for layer 320) in the order shown in FIG. 5 to obtain a penta-layer system (300). Thus, in our example, the unit layers (310), (330) and (350) are identical in terms of technological design and intrinsic properties. The same applies to unit layers (320) and (340).

### Step 3: Forming and Removing the First Upper Electrode Layer

This step can be subdivided into 2 or 3 sub-steps: deposition, possibly annealing and removal. The former provides a conductive layer which may be the same as or different from the lower electrode layer. In this example, a conductive layer (400) made of titanium nitride TiN with a thickness of 2 to 20 nm, in particular 10 nm, is selected, the intrinsic properties and methods of manufacture of which are identical to the lower electrode described in stage 1. The layer (400) is arranged on the penta-layer system (300) as shown in FIG. 6.

The deposition of the upper electrode (400) is followed by a thermal annealing step at 400° C. for 1 hour in a nitrogen atmosphere. Other annealing conditions and methods compatible with BEOL technology can be envisaged, such as rapid annealing or laser annealing. The aim of the annealing step is to impart a crystalline structure to the penta-layer system (300) under the combined effect of the thermal budget and the mechanical stress induced by the presence of the layer upper electrode (400). The preliminary phase of the predominantly amorphous HfO₂ unit layer is likely to favour transformation to a predominantly monoclinic phase after the thermal annealing step. A particular characteristic of the present disclosure is that it is possible to associate each unit layer (310, 330, 350) and (320, 340) making up the multilayer structure (300) to a particular crystalline orientation. After the annealing step, the majority phases observed are orthogonal and monoclinic, respectively, for the unit layer (3100, 3300, 3500) in ZrO₂ and the unit layer (3200, 3400) in HfO₂.

The removal of the unit layer (400) can be achieved using state-of-the-art techniques such as inductively coupled plasma reactive ion etching (ICP-RIE) using a halogenated gas-based chemistry (Cl₂, BCl₃, CHF₃) in combination with other gases (Ar, N₂, O₂, He). Other removal techniques chemical can be used to remove the titanium nitride layer, such as the mixture formed by the chemical elements ammonia hydroxide (NH₄OH), hydrogen peroxide H₂O₂ and deionised water H₂O heated to 60° C.

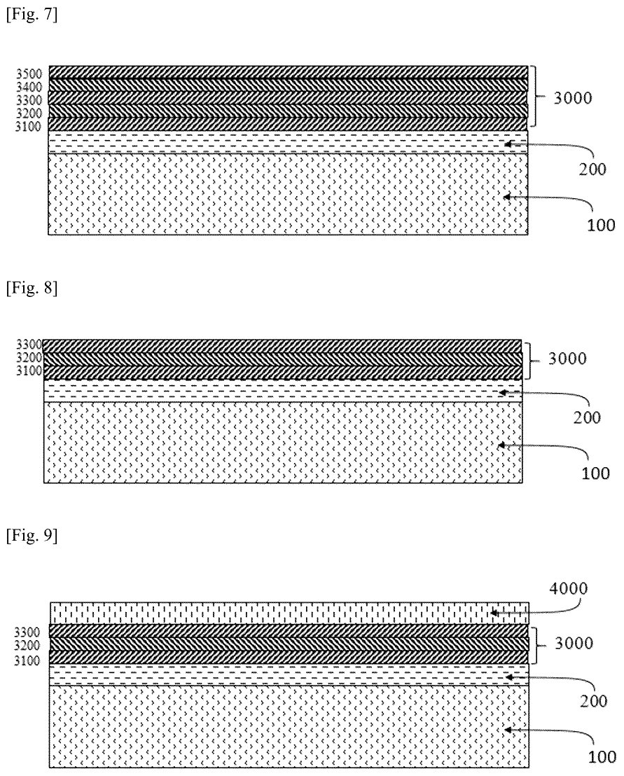

In this example (FIG. 7), it is possible to etch a layer (400) of TiN selectively, with respect to the single layer (3500) in particular and the multilayer system (3000) in 60s using the ICP-RIE technique using a CHF₃/Ar mixture (30% Ar, a gas flow of 120 sccm) at a temperature of 85° C. under a total pressure of 8 mTorr and a plasma power of 1 kW.

### Step 4: Thinning of the Anti-Ferroelectric Layer

One of the major advantages of the present disclosure lies in the use of a multi-layer system in which the basic unit layers (310, 330 and 350 on one side defining the material “A”; and 320 and 340 on the other side defining material “B”) are characterised by a very different crystalline orientation. Specifically, at the end of step 3, the initial ZrO₂ unit layers (310, 330, 350) are crystalline with a tetragonal majority phase which remains dominant after the annealing stage. On the other hand, the predominantly amorphous HfO₂ unit layers (320, 340) have become crystalline with a monoclinic majority phase and will be noted. The unit layers obtained after the annealing operation will be denoted (3100, 3200, 3300, 3400, 3500) respectively, thus forming a multilayer system denoted (3000) characterised by a predominantly tetragonal and/or orthorhombic crystalline phase.

The selective removal of the layer (400) allows direct access to the multilayer system. The thinning the anti-ferroelectric layer is the step that reduces the final thickness of the multilayer system. According to one of the configurations (FIG. 8), the purpose of step 4 is to remove the unit layer (3500) and the unit layer (3400) from the stack forming the initial multilayer system (3000).

Experimentally, step 4 uses ALE atomic layer etching techniques (for Atomic Layer Etching), which is highly suitable for ultra-thin single layers. This technique is based on a sequential injection of reactive gases separated by purge times according to a number of cycles established as a function of the thickness of the unit layer to be removed. In one embodiment, the selective removal of ZrO₂ and HfO₂ unit layers employs SF₄ chemistry (fluorination gas modifying the composition of the layer to be removed) and TiCl₄ (precursor metal for ligand exchange and removal of the desired layer). For a pressure of 1 Torr under a flow of neutral gas (N₂ or Ar) and a temperature set at 250° C., it is necessary to consider approximately 50 cycles and 300 cycles of SF₄ (exposure time Is and a purge of 30s) and TiCl₄ (exposure time Is and a purge of 30s) to remove respectively and completely the unit layers (350) of ZrO₂ and (340) of HfO₂ with T a thickness of 2 nm each. The conditions of ALE etching are given by way of example and depend mainly on the physicochemical and crystalline nature and thickness of the layers to be etched and the type of ALE equipment used.

Alternatively, the thinning and removal of the unit layers (3400 and 3500) can be carried out selectively in a suitable liquid solution, given that the etching speeds of the materials forming the two unit layers are significantly different. For example, the unit layer (3500) of ZrO₂ with a thickness of 2 nm can be removed after 30s of exposure to a 2.5% concentrated hydrofluoric acid (HF) solution heated to 80° C. In contrast, it only takes 5s of exposure in the same solution to remove 2 nm from the HfO₂ unit layer (3400).

The result of step 4 is a crystalline multilayer (3000) whose intrinsic properties are preserved compared with the layer (300) formed at the end of step 3 (deposition and thermal annealing). The anti-ferroelectric multilayer (3000) itself, with the desired properties, is finally obtained after the steps of thermal annealing, removal of the first upper electrode layer and the thinning step. The MAFM capacitance structure shown in FIG. 9 is constructed after deposition of a new upper electrode layer (4000) identical to the layer (400) without a further thermal annealing operation.

While illustrative embodiments have been illustrated and described, it will be appreciated that various changes can be made therein without departing from the spirit and scope of the claimed subject matter.

1. A method for preparing a multilayer anti-ferroelectric device M with n layers, n being between 2 and 100, device M comprising an alternation of at least one layer A and at least one layer B,
said at least one layer A independently consisting of a compound selected from zirconium oxides (ZrO₂), hafnium and zirconium oxides (H₂O) enriched with zirconium, and perovskites,
said at least one layer B being, independently, constituted by a compound selected from hafnium oxides (HfO₂), hafnium and zirconium oxides (H₂O) enriched with hafnium, hafnium and zirconium oxides (H₂O) doped with aluminium, hafnium and zirconium oxides (H₂O) doped with lanthanum, hafnium and zirconium oxides (H₂O) doped with gadolinium, hafnium and zirconium oxides (H₂O) doped with yttrium, oxides of hafnium and zirconium oxides (H₂O) doped with silicon, and hafnium oxides (HSO) doped with silicon,
said method comprising the following steps:
(i) a step of preparing, on a lower metal electrode, a multilayer device M′ with n′ layers, n′ being from 3 to 101, with n′>n, multilayer device M′ comprising an alternation of said layers A and B, the first of the n′ layers, in contact with the lower metal electrode, being a layer A,
(ii) a step of depositing on said multilayer device M′ obtained at the end of step (i), opposite said lower metal electrode, an upper metal electrode
(iii) a step of annealing the device obtained at the end of step (ii),
(iv) a step of removing the upper metal electrode from the device obtained at the end of step (iii),
(v) a selective etching of the n′-n upper layers, opposite the lower metal electrode, in order to obtain the multilayer device M on said lower metal electrode,
(vi) optionally, a step of depositing, on said multilayer device M′ obtained at the end of step (v), opposite said lower metal electrode, an upper metal electrode.

2. The method according to claim 1, wherein the last layer of the multilayer device M is a layer A.

3. The method according to claim 1, wherein the multilayer device M′ is prepared by successive deposition of layers A and B by an atomic layer deposition (ALD) technique, wherein the precursors of the hafnium and zirconium oxides are halogenated precursors, wherein said halogenated precursors are HfCl₄ and ZrCl₄.

4. The method according to claim 1, wherein the layers A and B of the multilayer devices M and of the multilayer device M′ have a thickness of between 0.5 and 5 nm.

5. The method according to claim 1, wherein the multilayer device M and the multilayer device M′ have a thickness of less than 50 nm.

6. The method according to claim 1, wherein the selective etching of step (v) is a wet or dry etch, said wet or dry etch comprising an atomic layer etching (ALE).

7. The method according to claim 1, wherein:
the layer A of the device M′ is predominantly tetragonal;
the layer A of the device M is predominantly tetragonal,
the layer B of the device M′ is predominantly amorphous;
the layer B of the device M is predominantly orthorhombic and/or monoclinic.

8. The method according to claim 1, wherein the annealing of step (iii) is carried out at a temperature of 300 to 600° C.

9. The method according to claim 1, wherein the metal electrode mentioned in relation to step (ii) and the metal electrode mentioned in relation to step (vi) are deposited by physical vapour deposition (PVD) or chemical vapour deposition (CVD).

10. The method according to claim 1, wherein the lower metal electrode mentioned in relation to step (i) is in contact, opposite the layer A, with a substrate comprising silicon, said metal electrode being deposited by physical vapour deposition (PVD) or chemical vapour deposition (CVD).

11. The method according to claim 1, wherein the metal electrode mentioned in relation to step (i), the metal electrode mentioned in relation to step (ii) and the metal electrode mentioned in relation to step (vi) consist of a metal, a material comprising said metal, or mixtures thereof.

12. The method according to claim 1, wherein the metal electrode mentioned in relation to step (i), the metal electrode mentioned in relation to step (ii) and the metal electrode mentioned in relation to step (vi) have a thickness of 2 to 500 nm.

13. The method of claim 1, wherein n is between 2 and 25.

14. The method of claim 1, wherein n′ is between 3 and 26.

15. The method of claim 4, wherein the layers A and B have a thickness of about 2 nm.

16. The method of claim 5, wherein multilayer device M and M′ have a thickness of less than or equal to 15 nm.

17. The method of claim 6, wherein the ALE is plasma etching (anisotropic) or thermal etching (isotropic).

18. The method of claim 8, wherein the annealing of step (iii) is carried out at a temperature of around 400° C.

19. The method of claim 11, wherein the metal is selected from the group consisting of titanium, gold, platinum, aluminum, ruthenium, molybdenum, copper, and tungsten.

20. The method of claim 11, wherein the material comprising said metal is a metal nitride, said metal nitride selected from the group consisting of TiN, WN, TaN, and MON.
